(19) United States
(12) Patent Application Publication
(10) Pub. No.: US 2015/0062856 A1
(43) Pub. Date: Mar. 5, 2015

(54) CONNECTION PORT CONFIGURING METHOD AND COMBINED CIRCUIT BOARD MODULE MOUNTED WITH MULTIPLE CONNECTION PORTS

(71) Applicant: GOOD WAY TECHNOLOGY CO., LTD., NEW TAIPEI CITY (TW)

(72) Inventor: YI-CHENG CHANG, NEW TAIPEI CITY (TW)

(73) Assignee: GOOD WAY TECHNOLOGY CO., LTD., NEW TAIPEI CITY (TW)

(21) Appl. No.: 14/016,438

(22) Filed: Sep. 3, 2013

(51) Int. Cl. H05K 7/02

(52) U.S. Cl. CPC H05K 7/026
USPC 361/803

(57) ABSTRACT

A connection port configuring method and a combined circuit board module mounted with multiple connection ports, characterized in that connection ports are mounted on a first circuit board and a second circuit board; the connection ports each comply with a communication port protocol and send a data at a transmission speed by the communication port protocol; the connection port configuring method involves assigning the connection ports to a high-speed connection port group and a low-speed connection port group according to the transmission speed of each connection port, mounting the connection ports of the high-speed connection port group on the first circuit board, and mounting the connection ports of the low-speed connection port group on the second circuit board. With a connection unit connecting the first circuit board and the second circuit board, the data can be transmitted between the first circuit board and the second circuit board.

### FIELD OF TECHNOLOGY

The present invention relates to configuring connection ports on a circuit board, and more particularly, to a connection port configuring method whereby multiple connection ports of different transmission speeds are mounted on at least two circuit boards and a combined circuit board module mounted with multiple connection ports.

### BACKGROUND

To meet most consumers' operational needs, commercially available circuit boards are usually characterized in that: a plurality of connection ports is mounted on a single circuit board, wherein, for example, the connection ports comply with communication port protocols applicable to Universal Serial Bus (USB), audio connection port (AC97), PS/2, Digital Visual Interface (DVI), or High Definition Multimedia Interface (HDMI). With the connection ports complying with different communication port protocols, the connection ports are different from each other in terms of transmission speed.

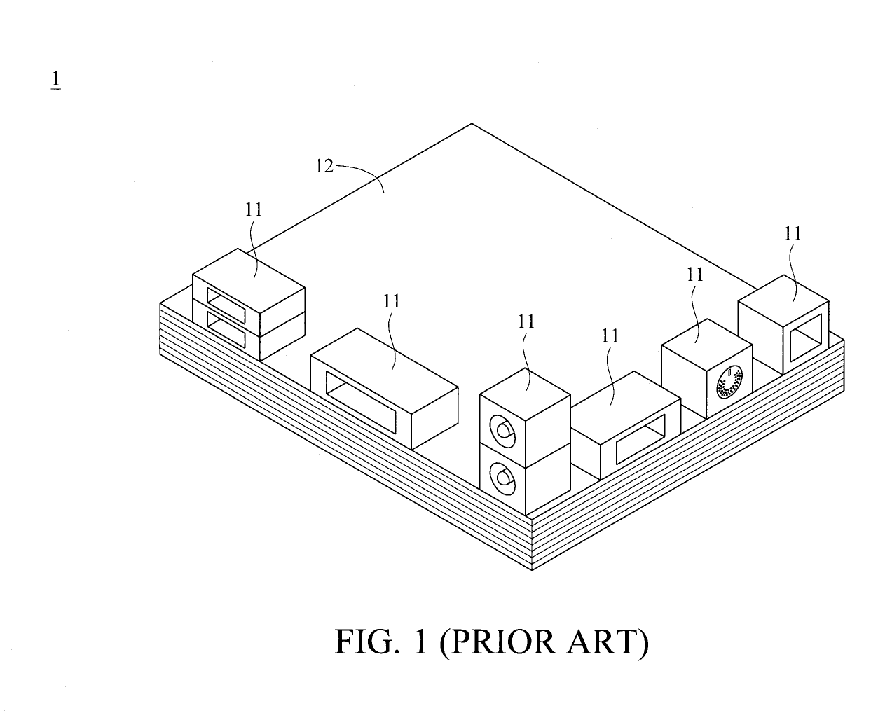

Referring to FIG. 1, there is shown a schematic perspective view of a conventional circuit board 1 and connection ports 11 mounted thereon. In general, not only does the degree of sophistication of required the circuit layout of the circuit board 1 increase with the transmission speed of the connection ports 11 mounted thereon, but the circuit board 1 is also a multilayer structure in order to meet the required specifications of the connection ports 11. Furthermore, connection ports of different transmission speeds are mounted on a commercially available circuit board; as a result, to meet the requirements for circuit layout of high-speed connection ports and facilitate the circuit board manufacturing process, it is necessary to use a circuit board that meets the highest specifications of the connection ports. To this end, conventional circuit boards are each of a multilayer structure at the expense of the high costs of circuit board manufacturing.

Accordingly, it is imperative to provide a connection port configuring method and a combined circuit board module mounted with multiple connection ports to overcome the drawbacks of the prior art.

### SUMMARY

It is an objective of the present invention to provide a connection port configuring method whereby not only are multiple connection ports of different transmission speeds categorized into a high-speed connection port group and a low-speed connection port group, but it is also feasible for the connection ports of the high-speed connection port group to be mounted on a high-speed circuit board and for the connection ports of the low-speed connection port group to be mounted on a low-speed circuit board, such that the connection ports of the low-speed connection port group do not increase the required area of the circuit layout of the high-speed circuit board, thereby cutting the manufacturing cost of the high-speed circuit board.

Another objective of the present invention is to provide a combined circuit board module mounted with multiple connection ports. The combined circuit board module comprises a high-speed circuit board and a low-speed circuit board, and multiple connection ports of different transmission speeds are mounted on the high-speed circuit board and the low-speed circuit board to thereby cut the manufacturing cost of the high-speed circuit board.

In order to achieve the above and other objectives, the present invention provides a connection port configuring method for mounting a plurality of connection ports on a first circuit board and a second circuit board. The connection ports each comply with a communication port protocol and send a data at a transmission speed according to the communication port protocol. The connection port configuring method comprises the steps of: setting a reference transmission speed; comparing the transmission speed of each of the connection ports with the reference transmission speed, assigning a said connection port to a first-category connection port group if the transmission speed of said connection port is higher than the reference transmission speed, and assigning a said connection port to a second-category connection port group if the transmission speed of said connection port is lower than the reference transmission speed; mounting the connection ports assigned to the first-category connection port group on the first circuit board and mounting the connection ports assigned to the second-category connection port group on the second circuit board; and connecting the first circuit board and the second circuit board by a connection unit, allowing the data to be transmitted from the first circuit board to the second circuit board via the connection unit, and allowing the data to be transmitted from the second circuit board to the first circuit board via the connection unit.

In order to achieve the above and other objectives, the present invention further provides a combined circuit board module mounted with multiple connection ports. The combined circuit board module comprises a first circuit board, a second circuit board, and a connection unit. The first circuit board has a first connection port and a first communication port. The first connection port sends and receives a data at a first transmission speed. The first communication port sends and receives the data at a second transmission speed. The second circuit board has a second connection port and a second communication port. The second connection port sends and receives the data at a third transmission speed. The second communication port sends and receives the data at the second transmission speed. The connection unit has a first connection end and a second connection end. The first connection end is connected to the first communication port. The second connection end is connected to the second communication port. The first transmission speed is not lower than the second transmission speed. The first transmission speed is higher than the third transmission speed.

Compared with the prior art, the present invention provides a connection port configuring method and a combined circuit board module mounted with multiple connection ports. The connection ports are categorized into a first-category connection port group and a second-category connection port group according to the transmission speeds of the connection ports. The connection ports of the first-category connection port group are mounted on a high-speed circuit board (hereinafter referred to as a first circuit board). The connection ports of the second-category connection port group are mounted on a low-speed circuit board (hereinafter referred to as a second circuit board). Since the connection ports of low transmission speeds are mounted on the second circuit board only, the second circuit board consists of relatively less layers and is still capable of data transmission.

A connection unit (such as a cable, a connector, or a flexible flat cable) connected between the first circuit board and the second circuit board is subjected to the transmission speed limitation of the connection ports of the second circuit board and thus only needs to operate at a low transmission speed in order to transmit a data between the first circuit board and the second circuit board.

### BRIEF DESCRIPTION

Objectives, features, and advantages of the present invention are hereunder illustrated with specific embodiments in conjunction with the accompanying drawings, in which:

FIG. 1 (PRIOR ART) is a schematic perspective view of a conventional circuit board and connection ports mounted thereon;

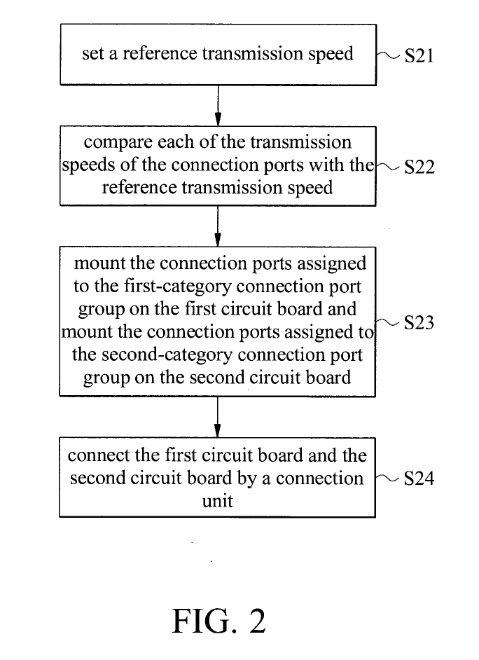

FIG. 2 is a schematic view of the process flow of a connection port configuring method according to an embodiment of the present invention; and

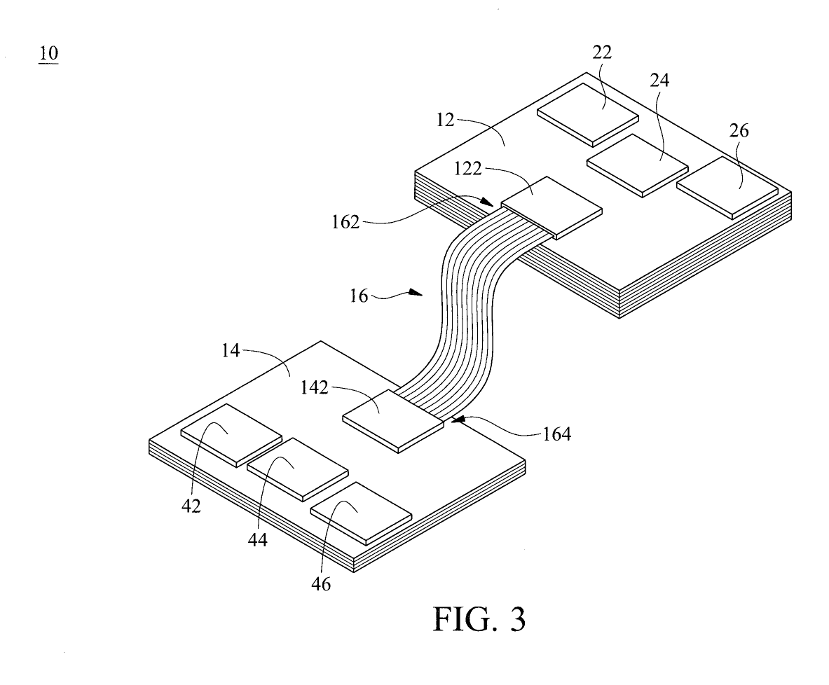

FIG. 3 is a schematic perspective view of a combined circuit board module according to an embodiment of the present invention.

### DETAILED DESCRIPTION

Referring to FIG. 2, there is shown a schematic view of the process flow of a connection port configuring method according to an embodiment of the present invention. As shown in FIG. 2, one of the purposes of the connection port configuring method is to mount a plurality of connection ports on a first circuit board and a second circuit board. In this embodiment, the first circuit board is mounted with the connection ports of a high transmission speed, whereas the second circuit board is mounted with the connection ports of a low transmission speed. The connection ports of a high transmission speed comply with at least one communication port protocol applicable to a Serial Advanced Technology Attachment (SATA), a Digital Visual Interface (DVI), a high-speed Universal Serial Bus, a Thunderbolt, a display port, a High Definition Multimedia Interface (HDMI), and/or a digital Ethernet interface. The connection ports of a low transmission speed comply with at least one communication port protocol applicable to a low-speed Universal Serial Bus, a PS/2 interface, a serial port, a COM port, and/or an analog Ethernet interface. The connection ports sends a data at a specific transmission speed according to the at least one communication port protocol.

The process flow of the connection port configuring method comprises step S21 through step S24 as follows:

Step S21: setting a reference transmission speed. The connection ports are categorized by making reference to the reference transmission speed.

Step S22: comparing each of the transmission speeds of the connection ports with the reference transmission speed. If the transmission speed of a connection port is higher than the reference transmission speed, the connection port is assigned to a first-category connection port group. If the transmission speed of a connection port is lower than the reference transmission speed, the connection port is assigned to a second-category connection port group.

Step S23: mounting the connection ports assigned to the first-category connection port group on the first circuit board and mounting the connection ports assigned to the second-category connection port group on the second circuit board.

Step S24: connecting the first circuit board and the second circuit board by a connection unit. A data is sent from the first circuit board to the second circuit board via the connection unit. A data is sent from the second circuit board to the first circuit board via the connection unit.

Referring to FIG. 3, there is shown a schematic perspective view of a combined circuit board module according to an embodiment of the present invention. As shown in FIG. 3, the combined circuit board module 10 is mounted with six connection ports 22, 24, 26, 42, 44, 46. The connection ports 22, 24, 26, 42, 44, 46 are each connected to an external electronic device (not shown), such that a data DA is not only transmitted from the connection ports 22, 24, 26, 42, 44, 46 to the electronic devices and vice versa, respectively, but also transmitted between the connection ports 22, 24, 26, 42, 44, 46. The connection ports 22, 24, 26 comply with at least one communication port protocol applicable to a high transmission speed. The connection ports 42, 44, 46 comply with at least one communication port protocol applicable to a low transmission speed. In this embodiment, the connection ports 22, 24, 26 transmit the data DA at a first transmission speed. The connection ports 42, 44, 46 transmit the data DA at a third transmission speed.

The combined circuit board module 10 comprises a first circuit board 12, a second circuit board 14, and a connection unit 16.

The first circuit board 12 is mounted with the connection ports 22, 24, 26 and a first communication port 122. The connection ports 22, 24, 26 each send and receive the data DA. The first communication port 122 sends and receives the data DA at a second transmission speed. In this embodiment, the first circuit board 12 is of an eight-layer structure.

The second circuit board 14 is mounted with the connection ports 42, 44, 46 and a second communication port 142. The connection ports 42, 44, 46 each send and receive the data DA. The second communication port 142 sends and receives the data DA at the second transmission speed. In this embodiment, the second circuit board 14 is of a four-layer structure.

The connection unit 16 comprises a first connection end 162 and a second connection end 164. For example, the connection unit 16 is a cable, a connector, or a flexible flat cable. In this embodiment, the connection unit 16 is exemplified by a flexible flat cable.

The first connection end 162 is connected to the first communication port 122. The second connection end 164 is connected to the second communication port 142.

The first transmission speed is not lower than the second transmission speed. The first transmission speed is higher than the third transmission speed.

In another embodiment, the combined circuit board module 10 further comprises a power connection port (not shown). The power connection port is mounted on the second circuit board 14.

In yet another embodiment, the combined circuit board module 10 further comprises an audio connection port (not shown). The audio connection port is mounted on the second circuit board 14.

Compared with conventional circuit boards, the present invention provides a connection port configuring method and a combined circuit board module mounted with multiple connection ports, characterized by assigning connection ports intended to be mounted on a circuit board to a first connection port group and a second connection port group, respectively, according to a transmission speed thereof, and positioning the first connection port group on the first circuit board and the second connection port group on the second circuit board. Since the second circuit board is not an expensive multilayer circuit board, the circuit board manufacturing process cost is lower than the conventional one.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A connection port configuring method for mounting a plurality of connection ports on a first circuit board and a second circuit board, the connection ports each complying with a communication port protocol and sending a data at a transmission speed by the communication port protocol, the connection port configuring method comprising the steps of:
setting a reference transmission speed;
comparing the transmission speed of each of the connection ports with the reference transmission speed, assigning a said connection port to a first-category connection port group if the transmission speed of said connection port is higher than the reference transmission speed, and assigning a said connection port to a second-category connection port group if the transmission speed of said connection port is lower than the reference transmission speed;
mounting the connection ports assigned to the first-category connection port group on the first circuit board and mounting the connection ports assigned to the second-category connection port group on the second circuit board; and
connecting the first circuit board and the second circuit board by a connection unit, allowing the data to be transmitted from the first circuit board to the second circuit board via the connection unit, and allowing the data to be transmitted from the second circuit board to the first circuit board via the connection unit.

2. A combined circuit board module mounted with multiple connection ports, the combined circuit board module comprising:
a first circuit board having a first connection port and a first communication port, the first connection port sending and receiving a data at a first transmission speed, and the first communication port sending and receiving the data at a second transmission speed;
a second circuit board having a second connection port and a second communication port, the second connection port sending and receiving the data at a third transmission speed, and the second communication port sending and receiving the data at the second transmission speed; and
a connection unit having a first connection end and a second connection end, the first connection end being connected to the first communication port, and the second connection end being connected to the second communication port,
wherein the first transmission speed is not lower than the second transmission speed, and the first transmission speed is higher than the third transmission speed.

3. The combined circuit board module of claim 2, further comprises a power connection port mounted on the second circuit board.

4. The combined circuit board module of claim 2, further comprising an audio connection port mounted on the second circuit board.

5. The combined circuit board module of claim 2, wherein the connection unit is one of a cable, a connector, and a flexible flat cable.

6. The combined circuit board module of claim 2, wherein the first connection port complies with at least a communication port protocol applicable to at least one selected from the group consisting of a Serial Advanced Technology Attachment (SATA), a Digital Visual Interface (DVI), a high-speed Universal Serial Bus, a Thunderbolt, a display port, a High Definition Multimedia Interface (HDMI), and a digital Ethernet interface.

7. The combined circuit board module of claim 2, wherein the second connection port complies with at least a communication port protocol applicable to at least one selected from the group consisting of a low-speed Universal Serial Bus, a PS/2 interface, a serial port, a COM port, and an analog Ethernet interface.
